(19) United States
(12) Patent Application Publication
(10) Pub. No.: US 2008/0149162 A1
(43) Pub. Date: Jun. 26, 2008

(54) Spectral Splitting-Based Radiation Concentration Photovoltaic System

(76) Inventors: Giuliano Martinelli, Ferrara (IT); Marco Stefancich, Ferrara (IT); Andrea Antonini, Alfonsine (IT)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(21) Appl. No.: 11/910,923

(22) PCT Filed: Apr. 7, 2006
(86) PCT No.: PCT/EP06/61435

§ 371 Date: Mar. 7, 2008

(30) Foreign Application Priority Data
Apr. 8, 2005 (IT) MI2005A000590

(51) Int. Cl. H01L 31/052; G02B 27/14

(52) U.S. Cl. 136/246; 359/634; 136/259

(57) ABSTRACT

A spectral splitting-based radiation concentration photovoltaic system is described, comprising one or more spectral splitting reflector elements, a photovoltaic concentrator, and a photovoltaic receiver.

### FIELD OF THE INVENTION

The present invention relates to a spectral splitting-based radiation concentration photovoltaic system, and in particular a reflective photovoltaic concentrator, a type of spectral beam-splitting reflector, a photovoltaic reflector, and a method for the conversion of solar energy into electricity using said photovoltaic system.

Radiant solar energy can be converted directly into electrical energy by means of photovoltaic devices (photovoltaic cells) that, in any case, have far higher costs with respect to conventional electricity generating techniques. The cost of the system is primarily connected to that of the material necessary for the photovoltaic cells and is therefore difficult to reduce.

A more economical solution than photovoltaic panels can be represented by the concentrator photovoltaic systems whereby an opportune optical system concentrates a great quantity of luminous radiation on a reduced surface of the specifically designed photovoltaic cells.

### STATE OF THE ART

In order to concentrate sunlight it is known to use incurved reflective elements that concentrate the sunlight on a small photovoltaic receiver.

For example, US patent application US2001/0036024 illustrates a solar concentrator comprising a dish to which a set of parabolically curved reflective elements is fixed that concentrate the sunlight on to a photovoltaic receiver.

The website “www.harbornet.com/sunflower” illustrates a solar concentrator comprising a dish to which a set of mirrors are fixed, arranged next to one another, incurved with respect to one of the two dimensions of the dish.

The above solar concentrators allow high concentration, thus promising, in prospect, a reduction in the costs of the photovoltaic system, however the limited efficiency of the silicon photovoltaic cells (less than 25%) remains a significant obstacle to their economic convenience.

Patent application EP-A2-1 126 529 shows a solar concentrator comprising a photovoltaic receiver and some flat mirrors, arranged around the photovoltaic receiver, which reflect sunlight towards the photovoltaic receiver.

This latter device makes it possible to obtain only a low concentration of sunlight (only a few times) and therefore does not allow a significant reduction in the system cost component associated to photovoltaic cells.

In the systems of the known type, the reflector has the mere purpose of concentrating sun radiation in a substantially independent way from the wavelength of the different components of the same radiation.

The photovoltaic cells based on a semiconductor material have, in any case, a limited global electrical efficiency if exposed to the entire solar radiation spectrum. In the conversion of solar energy into electricity by a semiconductor, the incident photons release electrons into the material, thus allowing them to move in the photovoltaic cell. In this process, photons, having energy lower than the band gap of the semiconductor, do not contribute to the process, whereas photons, having energies higher than the band gap, provide a net energetic contribution equal to the band gap whereas the excess energy is dissipated in heat. For this reason, a photovoltaic cell based on a specific semi-conductor material operates in a more efficient manner if exposed to radiation having energies slightly higher than the band gap thereof.

As different materials have different spectral regions of highest efficiency, it is possible, by splitting the radiation according to wavelength and sending to each device only the part where it operates best, in order to obtain a significantly higher overall electrical efficiency.

This is the approach followed, for example, in U.S. Pat. No. 2,949,498 whereby a photovoltaic converter is proposed obtained by stacking different types of photovoltaic cells. A high band gap cell is placed in front of one or more lower band gap cells. The photons, having greater energy, are absorbed by the former and those of lower energy are gradually absorbed and transformed by the subsequent cells. The drawback of this method is that each cell must be made transparent to the photons that do not provide a net electrical contribution thereto. Borden et al., Proceedings of the Fifteenth IEEE Photovoltaic Specialists Conference, pages 311-316 (1981) proposes a system whereby a dichroic mirror transmits high energy photons to a high band gap cell whilst it reflects the others on to lower band gap cells.

This method is disadvantageous as, if the dichroic system is placed in the focal of a concentration system, the dichroic mirrors are subject to a high light flow and to radiation originating from a large set of angles that, due to the functioning method of dichroic mirrors, makes functioning difficult. If on the other hand, the dichroics are used with unconcentrated radiation, the system in any way entails the use of large quantities of cells and does not develop the advantages of the concentration system.

The same applies for the proposal of Ludman et al., Proceedings of the Twenty-fourth IEEE Photovoltaic Specialists Conference, pages 1208-1211 (1994) whereby spectral splitting takes place by means of a diffraction reticule and the different types of cell are arranged opportunely so as to capture the radiation of the different wavelengths. If used in the focal of a concentration system, this system has drawbacks due to the large angle of origin of the radiation whereas if used in a flat system, the costs do not justify the advantages. It is also complex to obtain, in an economic manner, stable diffraction reticules for use in outdoor environments.

### SUMMARY OF THE INVENTION

Therefore, the purpose of this invention is to overcome all the abovementioned drawbacks and to indicate a radiation concentration photovoltaic system, based on spectral splitting, such as to increase in a substantial way the efficiency of the system through the spectral separation of solar radiation applied to a concentration system.

The scope of the present invention is a spectral splitting-based radiation concentration photovoltaic system, and in particular a reflective photovoltaic concentrator, a type of spectral beam-splitting reflector, a photovoltaic reflector, and a method for the conversion of solar energy into electricity using said photovoltaic system as in any one of the attached claims, which form an integral part of the present description.

The purposes and advantages of the present finding will be evident in view of the detailed description of one embodiment thereof, and of the variants thereof, and the appended drawings given by way of a non-limiting example, wherein:

### BRIEF DESCRIPTION OF THE FIGURES

FIGS. 1a and 1b illustrate an example of a spectral splitting reflector element according to a first embodiment of the present invention;

FIG. 2 illustrates an overview of one possible embodiment of a spectral splitting reflector photovoltaic concentrator according to a second embodiment of the present invention;

FIG. 3 illustrates a schematic overview of a possible photovoltaic system according to the invention;

FIG. 4 illustrates a schematic view of one example of embodiment of a photovoltaic receiver according to a further embodiment of the present invention;

FIG. 5 shows an embodiment example of movement and sun aiming means for said system.

In the figures, the same numbers identify the same elements.

### DETAILED DESCRIPTION OF THE INVENTION

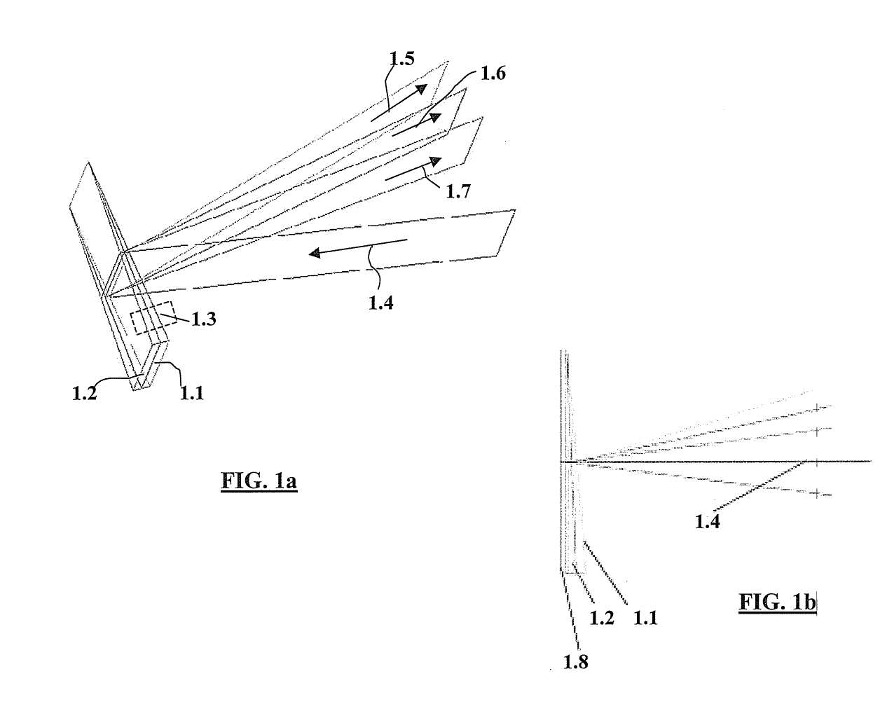

FIG. 1a illustrates an example of a spectral splitting reflector element constituted by two dichroic reflectors 1.1 and 1.2, each of which having flat and not parallel to one another anterior optical faces, defined secondary face, and posterior optical faces, defined primary face, making a reflector having a section 1.3 orthogonal to such trapezoidal shape faces, and assembled on a flat face receiver 1.8 (FIG. 1b).

In alternative, such spectral splitting reflector can be constituted by dichroic films slanting with respect to one another and held separate by air or other material with a refraction index close to 1.

In use, the dichroic reflectors 1.1 and 1.2 and the flat face reflector 1.8 are stacked and present the flat face reflector in the bottom position of the stack; each of said spectral splitting reflectors has as an optical axis a straight line orthogonal to the bottom surface of the set; the reflecting surface of said flat face reflector defines a principal face of the reflector, the reflecting surfaces of the dichroic reflectors define secondary faces.

The incident ray 1.4 is reflected and subdivided into different groups of rays reflected according to the characteristics of the dichroic surfaces used, for example in FIGS. 1.5, 1.6, 1.7, reflected by the anterior optical face, the intermediate face and posterior face, respectively.

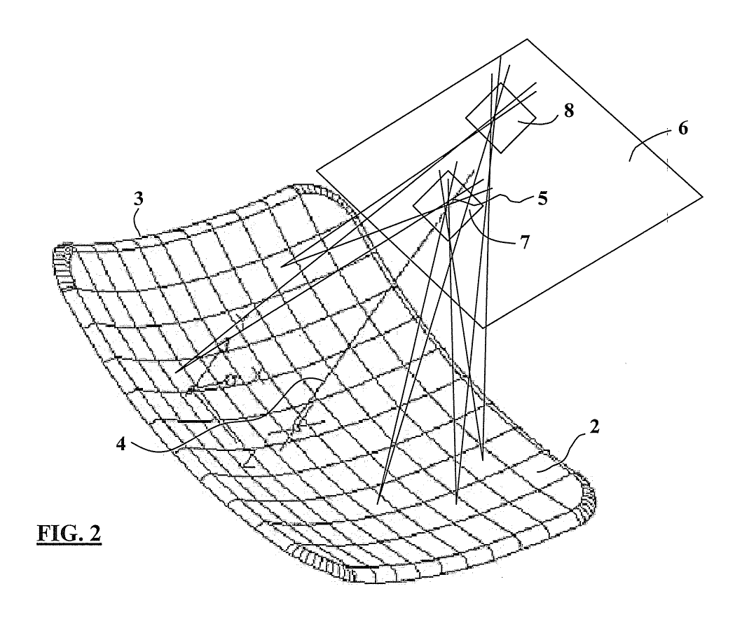

As illustrated in FIG. 2, a set of spectral splitting reflector elements 2 constitutes a spectral splitting photovoltaic concentrator, optionally assembled on a suitable support 3. Said elements are placed in opportune positions and lyings. It also illustrates the global optical axis 4 of said spectral splitting photovoltaic concentrator, defined as the straight line orthogonal to the bottom surface of the set and passing through its centre of gravity.

This system is constructed so that, as the solar radiation comes along the direction of the global optical axis 4, the rays reflected by the centres of the principal faces of the abovementioned reflector elements 2 cross at a point, named principal focus 5 of the system, placed at a specific distance from the concentrator, named principal focal distance.

The rays reflected by the primary faces of the spectral splitting reflector elements will therefore form on an opportunely oriented plane, passing through the principal focus 5, named principal focal plane 6, an area of concentrated lighting, defined principal caustic 7, where primarily light rays of defined wavelength are collected. With a similar procedure one or more secondary caustics 8 are defined, formed by the rays reflected by the secondary faces of the spectral splitting reflector elements, where the rays of different and defined spectral regions will be concentrated. Such caustics have a shape substantially coinciding with that of the faces of the corresponding spectral splitting reflector elements and, due to the flatness of the reflecting surfaces, they have a substantially uniform lighting intensity on the whole caustic.

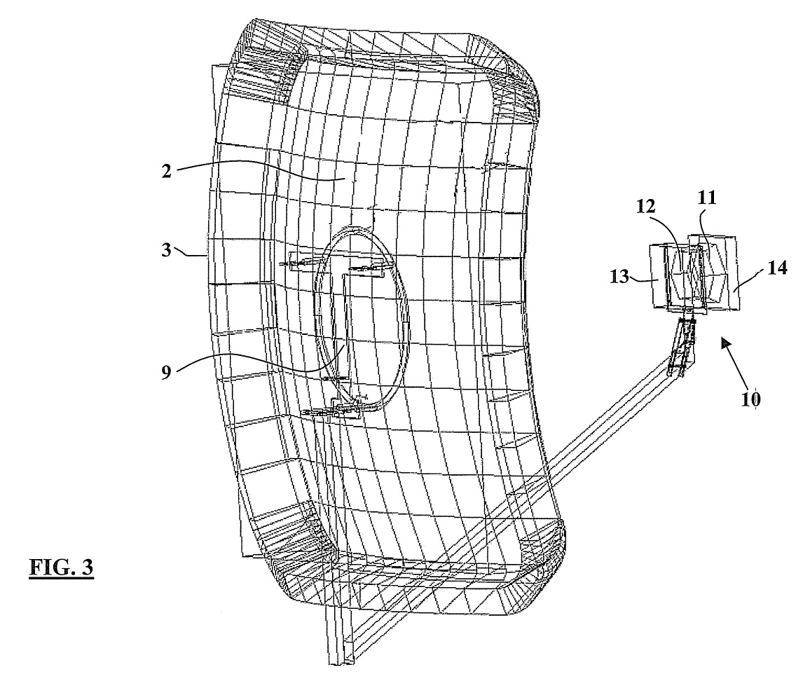

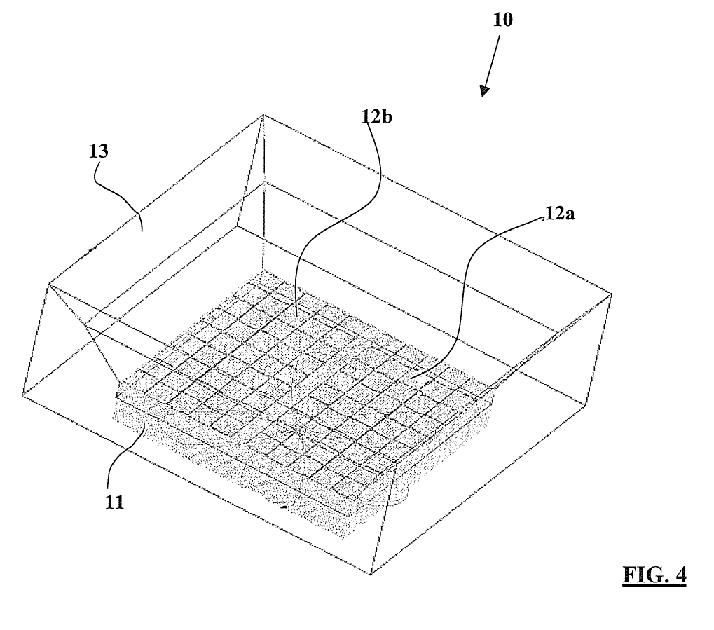

FIG. 3 illustrates a possible photovoltaic system, comprising a support 3, the various spectral splitting reflector elements 2, a support and fixing system 9 for the support 3 and for a photovoltaic receiver 10, also shown in FIG. 4. The latter is placed in the area constituted by the set of caustics, and is constituted so that each group of wavelengths falls on a specific type of photovoltaic cell.

The photovoltaic receiver 10 is placed in the focus 5 of the photovoltaic concentrator and is constituted essentially by a cooled support 11, one or more sets of photovoltaic cells of different types 12, an optional secondary concentration optical system 13, and a cooling system 14.

FIG. 4 illustrates an example of a photovoltaic cell set constituted by two groups of photovoltaic cells of different types 12a and 12b, one group for each caustic. The number of groups can also be higher.

The spectral splitting photovoltaic concentrator scope of the present invention therefore presents a multitude of spectral splitting receivers, having substantially flat faces but not parallel to each another, the number of which defines the optical concentration of the system and that form, through the solar rays reflected by the various optical surfaces, one or two concentrated lighting areas (caustics), each one comprising rays of specific wavelengths. The flatness of the reflecting surface makes it possible to obtain a substantially uniform lighting in the areas of concentrated lighting. The support may be constituted by a single piece or separated into several parts to reduce the wind load and to optionally simplify production.

In a possible embodiment of the photovoltaic concentrator, the support 3 may be made of plastic material, such as for instance ABS, or fibreglass, carbon fibre or metal.

The photovoltaic concentrator may envisage holes and/or cuts opportunely distributed to limit the wind load and to drain rainwater.

In each of the concentrated lighting areas (caustics) a specific photovoltaic receiver is placed, fitted with a plurality of photovoltaic cells (active elements), suited to the type of incident radiation. Such receiver is stationary with respect to the concentrator and receives the light directly therefrom. The lighting uniformity in the concentrated areas makes it possible to optimise the power produced by the photovoltaic panel and to prevent localised photovoltaic cell overheating.

This, combined with the spectral splitting of the radiation, constitutes a substantial innovation with respect to the known concentrators described above, for example, by US2001/0036024 and in the website www.harbornet.com/sunflower, where the solar radiation reflected on the photovoltaic receiver does not present uniform densities and is not spectrally split and with respect to Borden et al. whereby spectral splitting occurs but it is not concentration as also in the case of Jackson (U.S. Pat. No. 2,949,498) with respect to which it does not present the drawback of the transparency of the upper elements of the photovoltaic stack.

The number of the splitting reflector elements used can be changed as desired, without modifying the substance of the system, consequently modifying the optical concentration on the active elements. In the preferred embodiment, the spectral splitting reflector elements have a substantially square shape as also the concentrated areas formed thereby.

The spectral splitting reflector elements may then be applied to the support 3 by means of specific adhesives, mechanic fixing points (such as, but not exclusively, screws or plastic pins) and be constituted by suitably treated glass structures or acrylic structures.

In an embodiment such spectral splitting reflectors are constituted by an acrylic resin wedge, or generic transparent material, whose rear face (that constitutes the primary face) is made reflective, and the other face is fitted with a dichroic reflective layer. Optional further dichroic systems can be constituted by further transparent wedges the posterior, transparent face of which coincides with the anterior face of the previous one and on whose upper face a further dichroic reflective layer is applied (see FIG. 1).

The photovoltaic receiver can be fitted with air or liquid, forced or natural circulation cooling means 14 (FIG. 3), made according to the known art in order to keep the running temperature of the active elements under control.

The photovoltaic concentrator also comprises movement and sun aiming means that keep the system's global optical axis in the direction of the sun during the daylight hours.

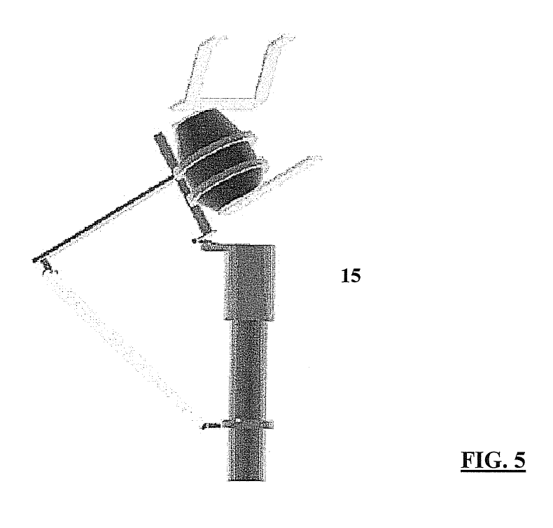

As shown in FIG. 5, such movement and sun aiming means comprise a motorised support 15 that supports the system and permits the movement thereof in the two directions needed for sun aiming.

In one embodiment of the system, such support/aiming structure can be of the altazimuth type, according to the definition used in astronomy, i.e. of the type comprising a first axis of rotation, parallel to the local vertical, and a second axis of rotation, perpendicular to the first and parallel to the horizontal plane.

In a second embodiment, the motorised frame can be of the equatorial type i.e. of the type comprising a first axis of rotation, parallel to the polar axis, and a second axis of rotation, perpendicular to the polar axis and parallel to the equatorial plane. One advantage of this solution is that, during daytime aiming, the use of a single motor is required, driven at a constant velocity.

The electronic automatic sun aiming system comprises a solar sensor, comprised, in a possible embodiment thereof, by a plurality of opportunely positioned directional photodiodes.

In a further alternative embodiment, the solar sensor may be constituted by an integrated array of Charge Couplet Devices (CCD) that dialogues, by means of an opportune protocol, with the control electronics constructed according to the known art.

In a further embodiment, such aiming system can be integrated by a system for calculating the astronomical position of the sun and feedback on the position of the motors that enables positioning independently even of the solar sensor.

In all cases, the signal of the specific sensor and the optional system for the calculation of the sun's astronomical position and the feedback signal of the motors are provided to an electronic system that performs motor control. The movement system motors act in a direction depending on the sensor signal and optional further data available until achieving a preset lighting condition of the sensor.

The method for the conversion of radiant solar energy into electrical energy by means of solar spectrum splitting, a further scope of the present invention, envisages the following phases:

1) Arranging a spectral splitting photovoltaic concentrator comprising spectral splitting reflector elements as described above.

2) Reflecting the sunlight on to the photovoltaic concentrator, so as to present two or more areas with substantially uniform lighting (caustics), each one primarily formed of photons with wavelengths within defined intervals. One possible embodiment could, for instance, separate wavelengths between 650 nm and 1200 nm from those of between 400 and 650 nm.

3) Placing in correspondence with said areas on the principal focal plane groups of specific photovoltaic cells for incident radiation. For example made of silicon, to convert wavelengths of over 650 nm and of InGaP (Indium Gallium Phosphorus) that constitute a broad band photovoltaic cell for those below.

4) Collecting the current generated by said cells, for example by welded electrical contacts placed on the front and back of the cell (or on the back only, in the case of opportune type cells), and sending it to opportune inverter systems or batteries according to the conventions of electrical installation practice. The individual cells can be connected to one another in series or parallel in order to obtain the combination of voltage and current best suited to the electric sets connected thereto according to the conventions of electrical installation practice.

Those skilled in the art will be able to make variants to the non-limiting example described, all of which being contemplated within the scope of protection of this invention, including all the equivalent embodiments.

Using the description given above, those skilled in the art are able to realise the object of the invention, without introducing further construction details.

1. Spectral splitting reflector, wherein it comprises—one or more dichroic reflectors having flat, and not parallel to one another, anterior and posterior optical faces;—a reflector with flat, parallel faces; said one or more dichroic reflectors and said flat parallel face reflector being stacked and having said flat face reflector in the bottom position of the stack; each of said spectral splitting reflectors having as an optical axis a straight line orthogonal to the lower surface of the set; the reflective surface of said reflector with flat parallel faces defining a principal face of the reflector, the reflective surface of said one or more dichroic reflectors defining one or more secondary faces.

2. Spectral splitting reflector as in claim 1, wherein said one or more dichroic reflectors are transparent to non-reflected frequencies.

3. Spectral splitting reflector according to claim 1, wherein said one or more dichroic reflectors comprise dichroic films slanting with respect to one another and held separated by air or other material with a refraction index close to 1.

4. Spectral splitting reflector according to claim 1, wherein said one or more dichroic reflectors comprise an acrylic resin wedge, or generic transparent material, whose rear face, which constitutes the primary face, is made reflective, and the other face is fitted with a dichroic reflective layer.

5. Spectral splitting reflector according to claim 4, wherein said one or more stacked dichroic reflectors have the respective transparent wedges, whose rear, transparent, face coincides with the anterior face of the previous one and on whose upper face a further dichroic reflective layer is applied.

6. Photovoltaic concentrator wherein it comprises a plurality of said spectral splitting reflective elements, according to claim 1, firmly joined, in order to define a global optical axis of said concentrator, such that, by placing said global optical axis in the direction of an incident radiation, the rays reflected by said principal faces cross in a point defined principal focal of the concentrator, and so that different spatially separate areas exist, lying on one plane passing through said principal focal where the rays reflected by said primary and secondary faces form areas, defined respectively primary and secondary caustics of concentrated light, constituted mainly by radiation of specific wavelengths.

7. Photovoltaic concentrator according to claim 6, wherein it is made on a rigid support of plastic material, such as for instance ABS, or fibreglass, carbon fibre or metal.

8. Photovoltaic concentrator according to claim 7, wherein it comprises holes and/or cuts to limit the wind load and to drain rain water.

9. Photovoltaic concentrator as in claim 7, wherein it is constituted by a single piece or separated into several parts in order to reduce the wind load.

10. Photovoltaic concentrator, according to claim 7, wherein said spectral splitting reflector elements are applied to said support by means of specific adhesives, mechanic fixing points and/or they comprise glass structures or acrylic structures.

11. Photovoltaic receiver, wherein it comprises two or more groups of photovoltaic cells, spatially separated and based on different types of cells for the generation of electric current by different spectral components of the concentrated beam of light received by said concentrator according to claim 6, positioned on said plane passing through said principal focal at the said primary and secondary caustics, one group for each caustic.

12. Photovoltaic receiver according to claim 11, wherein it further comprises a cooled support, a secondary concentration optical system, and a cooling system.

13. Photovoltaic receiver according to claim 12, wherein said cooling system is air or liquid powered, with forced or natural circulation.

14. A spectral splitting-based radiation concentration photovoltaic system, wherein it comprises one or more spectral splitting reflector elements comprising
one or more dichroic reflectors having flat, and not parallel to one another, anterior and posterior optical faces;
a reflector with flat, parallel faces;
said one or more dichroic reflectors and said flat parallel face reflector being stacked and having said flat face reflector in the bottom position of the stack;
each of said spectral splitting reflectors having as an optical axis a straight line orthogonal to the lower surface of the set;
the reflective surface of said reflector with flat parallel faces defining a principal face of the reflector, the reflective surface of said one or more dichroic reflectors defining one or more secondary faces; a photovoltaic concentrator,
comprising a plurality of said spectral splitting reflective elements, firmly joined, in order to define a global optical axis of said concentrator, such that, by placing said global optical axis in the direction of an incident radiation, the rays reflected by said principal faces cross in a point defined principal focal of the concentrator, and so that different spatially separate areas exist, lying on one plane passing through said principal focal, where the rays reflected by said primary and secondary faces form areas, defined respectively primary and secondary caustics of concentrated light, constituted mainly by radiation of specific wavelengths;
and a photovoltaic receiver according to comprising two or more groups of photovoltaic cells, spatially separated and based on different types of cells for the generation of electric current by different spectral components of the concentrated beam of light received by said concentrator, positioned on said plane passing through said principal focal at the said primary and secondary caustics, one group for each caustic.

15. Photovoltaic system according to claim 14, wherein it further comprises movement and aiming means of said incident radiation, that keep the global optical axis in the direction of said incident radiation.

16. Photovoltaic system according to claim 15, wherein said movement and sun aiming means comprise a motorised support that supports the system and permits the movement thereof in the two directions needed for said movement and aiming.

17. Photovoltaic system according to claim 15, wherein said movement and aiming means are of the altazimuth or equatorial type.

18. Method for the conversion of radiant solar energy into electrical energy by means of solar spectrum splitting, comprising the following steps:
a) providing one or more spectral splitting reflectors, each comprising:
one or more dichroic reflectors having flat, and not parallel to one another, anterior and posterior optical faces;
a reflector with flat, parallel faces;
said one or more dichroic reflectors and said flat parallel face reflector being stacked and having said flat face reflector in the bottom position of the stack;
each of said spectral splitting reflectors having as an optical axis a straight line orthogonal to the lower surface of the set,
the reflective surface of said reflector with flat parallel faces defining a principal face of the reflector, the reflective surface of said one or more dichroic reflectors defining one or more secondary faces;
b) arranging a photovoltaic concentrator comprising a plurality of said spectral splitting reflector elements, firmly joined, in order to define a global optical axis of said concentrator, such that, by placing said global optical axis in the direction of an incident radiation, the rays reflected by said principal faces cross in a point defined principal focal of the concentrator, and so that different spatially separate areas exist, lying on one plane passing through said principal focal, where the rays reflected by said primary and secondary faces form areas, defined respectively primary and secondary caustics of concentrated light, constituted mainly by radiation of specific wavelengths.
c) malting sunlight reflect on the photovoltaic concentrator, so as to present two or more areas with substantially uniform lighting (caustics), each one primarily formed of photons with wavelengths within defined intervals;
d) placing in correspondence with said areas on the principal focal plane groups of photovoltaic cells, spatially separated and based on different types of cells for the generation of electric current by different spectral components of the concentrated beam of light received by said concentrator, positioned on said plane passing through said principal focal at the said primary and secondary caustics, one group for each caustic.
e) collecting a current generated by said photovoltaic cells.

19. Method according to claim 18, wherein said photovoltaic cells can be connected to one another in series or parallel in order to obtain determined combinations of voltage and electric current.

20. Method according to claim 18, wherein said photons of wavelengths within defined intervals comprise the intervals between 650 nm and 1200 nm and between 400 and 650 nm.

21. Method according to claim 18, wherein said photovoltaic cells are made in silicon, for wavelengths over 650 mn and InGaP (Indium Gallium Phosphide) for wavelengths lower than 650 nm.
